(19) United States
(12) Patent Application Publication
(10) Pub. No.: US 2014/0374862 A1
(43) Pub. Date: Dec. 25, 2014

(54) CMOS Image Sensor With Integrated Silicon Color Filters

(71) Applicant: OmniVision Technologies, Inc., Santa Clara, CA (US)

(72) Inventors: ChiaYing Liu, Hsinchu City (TW); Keh-Chiang Ku, Cupertino, CA (US); Dyson Hsinchih Tai, San Jose, CA (US); WuZhang Yang, Shi-Hu (TW)

(73) Assignee: OmniVision Technologies, Inc.

(21) Appl. No.: 13/921,901

(22) Filed: Jun. 19, 2013

(51) Int. Cl. H01L 27/146

(52) U.S. Cl. CPC H01L 27/14627; H01L 27/14685
USPC 257/432; 438/70

(57) ABSTRACT

A color photosensor array has photosensors of a first type having a thick overlying silicon layer, photosensors of a second type having a thin overlying silicon layer, and photosensors of a third type having no overlying silicon layer; the photosensors of the first type having peak sensitivity in the red, the photosensors of the second type having peak sensitivity in the green. In particular embodiments, color correction circuitry is provided to enhance color saturation.

### BACKGROUND

The majority of electronic cameras marketed today are color cameras. In modern single-photosensor-array color cameras, the photosensor is typically tiled with a repeating pattern of at least three photosensor types, where each type has a different spectral response. Most such photosensor arrays use an array of red, green, and blue filters, where one filter may be positioned over each photosensor of the array to produce the tiling pattern with at least one filter of each type present in each instance of the tiling pattern.

For example, in a typical tiling pattern 100 of a typical photosensor, a red 102, a green 104, and a blue 106 filter are positioned over photosensors of the array. In existing color photosensor arrays, the fourth photosensor may be covered by a filter 108 of any one of red, green, or blue, or left without a filter.

It is also known that high energy ion implants, such as are necessary to create deep diffused regions and deep junctions without extensive drive-in steps, can cause damage to crystal lattice structure. Damaged crystal structure is undesirable because it can cause leakage and mismatches between adjacent photosensors.

### SUMMARY

A color photosensor array comprising photosensors of a first type having a thick overlying silicon layer, photosensors of a second type having a thin overlying silicon layer, and photosensors of a third type having no overlying silicon layer; the photosensors of the first type having peak sensitivity in the red, the photosensors of the second type having peak sensitivity in the green.

### BRIEF DESCRIPTION OF THE FIGURES

FIG. 1 illustrates a typical tiling pattern as used on PRIOR ART color-filter cameras.

FIG. 2 is a schematic cross-sectional diagram illustrating PRIOR ART photosensors with color filters.

FIG. 3 is a schematic cross-sectional diagram illustrating photosensors with integrated silicon color filters.

FIG. 4 illustrates a very coarse approximation of spectral sensitivity of each photosensor type illustrated in FIG. 3.

FIG. 5 illustrates color-processing circuit that can provide conventional red, green, and blue color output from the photosensors illustrated in FIG. 3

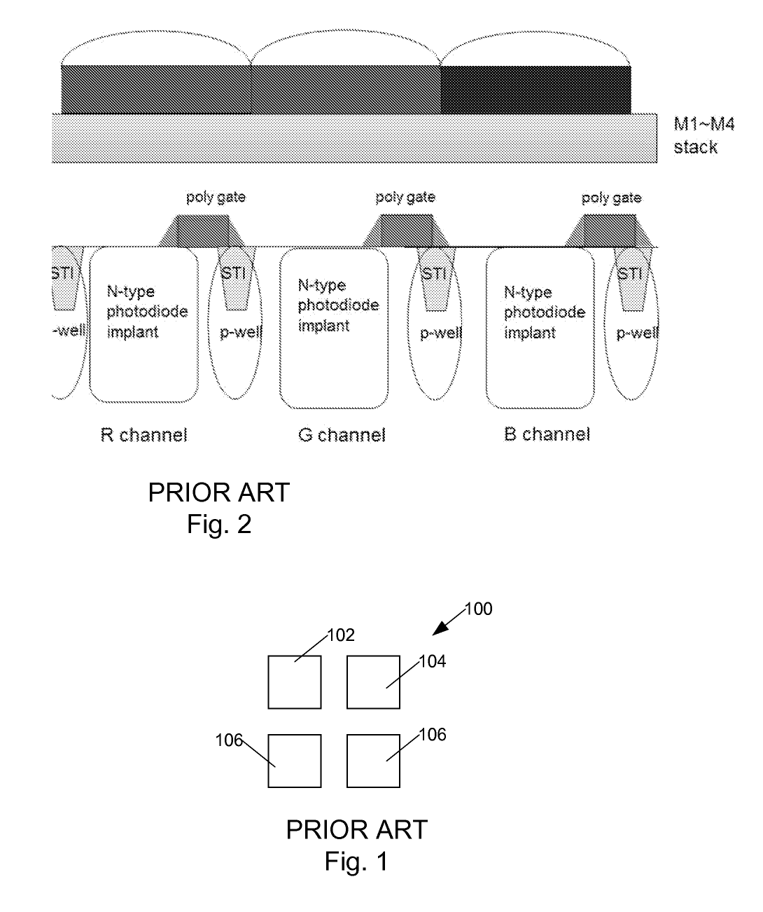

### DETAILED DESCRIPTION OF THE EMBODIMENTS

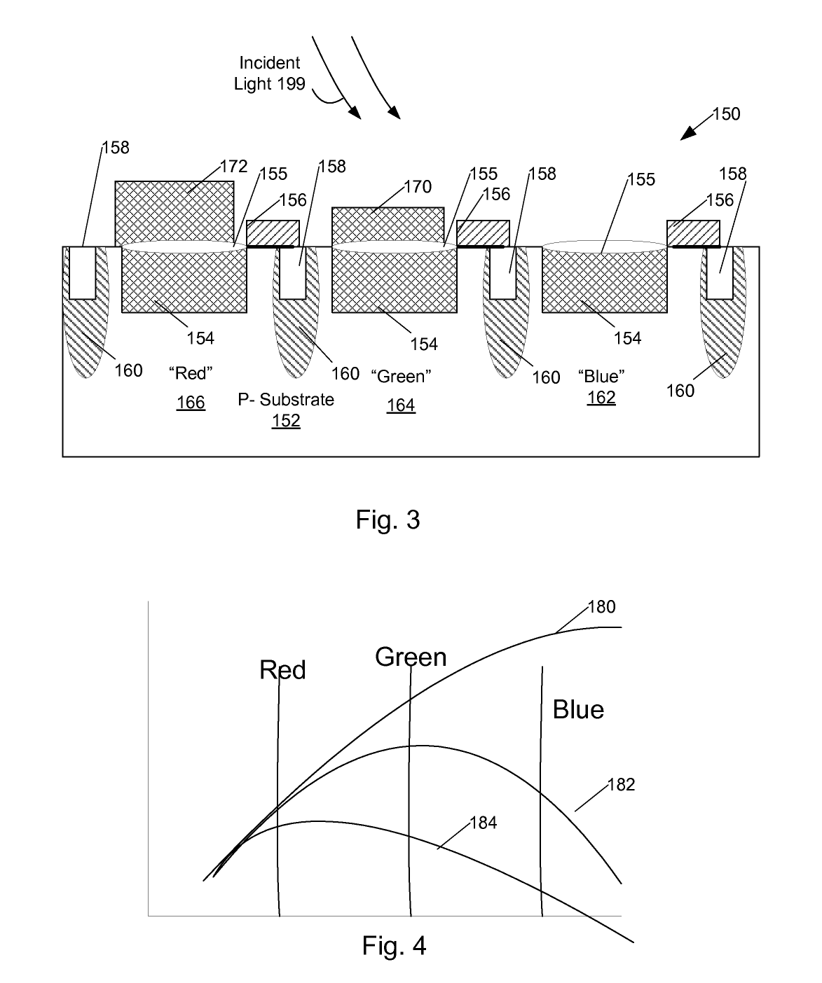

In a photosensor array 150 (FIG. 3), a P- substrate 152 has diffused N absorber regions 154 of photosensors as known in the art of silicon CMOS photosensor arrays. Each N region 154 is coupled through a row selection gate 156 to a diffusion 158 in a P well 160 that is coupled through reset and sensing circuitry (not shown) to a column line (not shown). Reset and sensing circuitry resembles that standard in the art. Each N absorber region is capped with a shallow P+type pinning region 155, except for adjacent row selection gate 156. The photosensors of array 150 are of three types, designated Blue 162, Green 164, and Red 166. The N absorber region 154 of the blue sensor 162 type is bare of covering silicon other than the pinning layer. The N absorber region 154 of the green sensor 164 type is has a covering epitaxially-grown, single-crystal, silicon, filter layer 170 of a first thickness atop the pinning layer, which in a particular embodiment is approximately 0.6 micron. The N absorber region 154 of the red sensor 166 type covered by epitaxially-grown, single-crystal, silicon, filter layer 172 of a second thickness, which in a particular embodiment is approximately 1.2 micron.

The three distinct types of photosensors are prepared by using photomask-patterned blocking oxides to prevent deposition on photodiodes where expitaxial growth is not wanted, and removing that oxide where expitaxial growth is desired. For example, in a particular embodiment, an oxide is present over the blue 162 absorber region while not present over the absorber regions of red 166 and green 164 photosensors while the first thickness of expitaxial silicon is grown, and present over absorber regions of both the green 164 and blue 162 absorber regions, while epitaxial silicon of thickness equal to the difference between second and first thickness of epitaxial silicon is grown on the red 166 absorber region. In alternative embodiments, other maskable layers may be used to determine presence and absence, and thickness, of epitaxial silicon over the absorber regions.

The three types of photosensors illustrated in FIG. 3 have different effective spectral response. In part, this difference in response is due to absorption in the filter layers of silicon atop two of the three types of photosensors, in which blue light is absorbed at the first thickness over the green photo sensor 164, and both blue and green light is absorbed at the second thickness over the red photosensor 166. Since both blue and green light is absorbed before photons reach the red photosensor 166 absorber layer, the red photosensor has peak sensitivity in red wavelengths. Further, longer wavelengths of light tend to penetrate the relatively thin absorber layer before being absorbed, as such the blue sensor has peak absorption in blue wavelengths. In an embodiment, signals associate with the red sensor form a red channel, the blue sensor form a blue channel, and the green sensor a green channel; all 3 channels are read to a host processor.

The blue sensor 162 has a spectral response approximating the curve 180 in FIG. 4 because there is no absorption by filter layers above it, and because most blue light is absorbed by its N absorber region. As wavelength increases, increasing proportions of photons penetrate the layer into the substrate, such that the blue sensor absorber region absorbs fewer green and still fewer red photons that strike it.

The green sensor 164 has a spectral response approximating curve 182 because most blue photons are absorbed in the overlying thin silicon layer 170, while many longer-wavelength red and green photons penetrate filter layer 170 and reach its absorber 154. Some green, and many red, photons penetrate the absorber region without being absorbed, the result is peak sensitivity in the green.

The red sensor 166 has a spectral response approximating curve 184 because not only are blue photons absorbed by the thick silicon layer 172, but so are most of the green photons. This leaves primarily red photons to reach its absorber 154. Some red photons penetrated the absorber without being absorbed and detected. This sensor therefore has a lower sensitivity than the green or blue sensors, but has a peak spectral response in the red.

In a particular embodiment, junction depth of the absorbers 154 is the same for red, green, and blue photosensors.

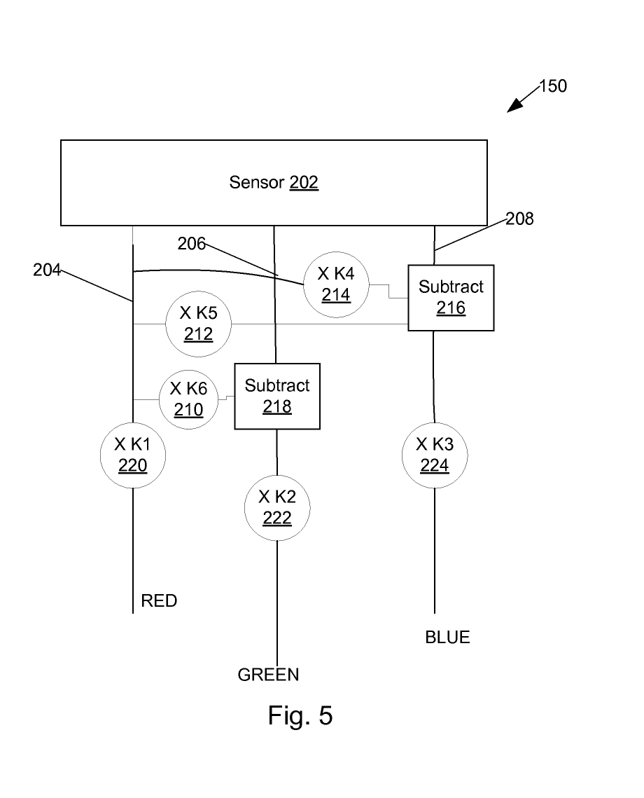

In a camera system 200 (FIG. 5) using the sensors of FIG. 3, light from a scene is focused and applied as incident light 199 of an image to the photosensor array. The photosensor array is tiled with a tiling pattern pattern including at least one of each of the red 162, green 164, and blue 166 photosensor types, the array including many thousands of tiling patterns organized in a rectangular array. The photosensor array is reset and sensed by associated electronics, not shown, similar to that used for other photosensors used on integrated photosensor array integrated circuits. The photosensor array 202 produces three channels, a red or long-wavelength channel 204, a medium wavelength or green channel 206, and a short or blue wavelength channel 208, the red channel 204 providing signals representing to illumination of red sensors 166, the green channel 206 providing signals representing to illumination of green sensors 164, and the blue channel 206 providing signals representing illumination of red sensors 162; the signals of the three channels corresponding to a color representation of the image. In an embodiment, color correction circuitry is provided to improve color saturation of red, blue, and green channels.

In a particular embodiment of color correction circuitry, as illustrated in FIG. 5, the blue channel 208 is corrected by multiplying the red channel 204 by a constant K4 in multiplier 214, and the medium wavelength channel by a second constant K5 in multiplier 212, and subtracting these signals in a subtractor 216 from the blue channel 208, then multiplying the blue channel by another constant K3 in multiplier 224 to produce an output similar to a conventional BLUE channel. Similarly, the green channel 206 is corrected by multiplying the red channel 204 by a constant K6 in multiplier 210, and subtracting 218 this from the medium wavelength channel 206, then multiplying by another constant K2 in multiplier 222 to produce an output similar to a conventional GREEN channel. The red or long-wavelength channel 204 need only be multiplied by a constant K1 in multiplier 220 to produce an output similar to a conventional RED channel and thereby compensate for its lower sensitivity.

In all embodiments, additional layers, such as a transparent oxide layer or other scratch protection and passivation layer, is deposited across the top of all three types of sensors illustrated in FIG. 3, including red 166, green 164, and blue 162.

In an alternative embodiment, where light of red wavelengths is not significantly absorbed in filter regions 172 and 170 but is absorbed in absorber region 154 of red sensor 166, and red light is less significantly absorbed than previously discussed in absorber region 154 of green sensor 164, but green light is largely absorbed in absorber region 154 of green sensor 164, subtractors 216, 218 may be omitted from the color processing circuitry illustrated in FIG. 5.

It is expected that the RED, GREEN, and BLUE outputs of the color processing circuitry illustrated in FIG. 5 are subjected to additional color processing for white balancing.

### Combinations

A color photosensor array designated A including photosensors of a first type having a thick overlying silicon filter layer, photosensors of a second type having a thin overlying silicon filter layer, and photosensors of a third type having no overlying silicon layer; the photosensors of the first type having peak sensitivity in the red, the photosensors of the second type having peak sensitivity in the green.

A color photosensor array designated AA including the photosensor array designated A wherein the thick overlying silicon layer and the thin overlying silicon layer are single-crystal silicon layers grown atop an implanted pinning region, an absorber layer of each photosensor underlying the pinning region.

A color photosensor array designated AB including the photosensor array designated A or AA wherein the thick overlying silicon filter layer is approximately 1.2 microns thick.

A color photosensor array designated AC including the photosensor array designated A, AA or AB wherein the thin overlying silicon filter layer is approximately 0.6 microns thick.

A color photosensor array designated AD including the photosensor array designated A, AA, AB or AC further comprising color correction circuitry.

A color photosensor array designated AE including the photosensor array designated AD wherein the color correction circuitry comprises at least two multipliers and at least one subtractor, configured such that a green output is determined by subtracting a multiple of a signal derived from photosensors of the first type from a multiple of a signal derived from photosensors of the second type.

A method designated B of providing a red, a green, and a blue signal representing a color image including providing a color photosensor array comprising photosensors of a first type having a thick overlying silicon filter layer, photosensors of a second type having a thin overlying silicon filter layer, and photosensors of a third type having no overlying silicon layer; the photosensors of the first type having peak sensitivity in the red, the photosensors of the second type having peak sensitivity in the green; focusing light from a scene on the photosensor array as an optical image; and sensing photosensors of the first type to provide the red signal, the second type to provide the green signal, and the third type to provide the blue signal, the red green and blue signals together forming an electronic representation of the optical image.

A method designated BA including the method designated B wherein the thick overlying silicon layer and the thin overlying silicon layer are single-crystal silicon layers grown atop an implanted pinning region, an absorber layer of each photosensor underlying the pinning region.

A method designated BB including the method designated B or BA wherein the thick overlying silicon filter layer is approximately 1.2 microns thick.

A method designated BC including the method designated B, BA, or BB wherein the thin overlying silicon filter layer is approximately 0.6 microns thick.

A method designated BD including the method designated B, BA, BB, or BC and further including passing the red, green, and blue signals through color correction circuitry to improve color resolution of the image.

A method designated BE including the method designated BD wherein the color correction circuitry is configured such that a corrected green output signal is determined by subtracting a multiple of the red signal from a multiple of the green signal.

Changes may be made in the above methods and systems without departing from the scope hereof. It should thus be noted that the matter contained in the above description and shown in the accompanying drawings should be interpreted as illustrative and not in a limiting sense. The following claims are intended to cover generic and specific features described herein, as well as all statements of the scope of the present method and system, which, as a matter of language, might be said to fall therebetween.

What is claimed is:

1. A color photosensor array comprising photosensors of a first type having a thick overlying silicon filter layer, photosensors of a second type having a thin overlying silicon filter layer, and photosensors of a third type having no overlying silicon layer; the photosensors of the first type having peak sensitivity in the red, the photosensors of the second type having peak sensitivity in the green.

2. The photosensor array of claim 2 wherein the thick overlying silicon layer and the thin overlying silicon layer are single-crystal silicon layers grown atop an implanted pinning region, an absorber layer of each photosensor underlying the pinning region.

3. The photosensor array of claim 2 wherein the thick overlying silicon filter layer is approximately 1.2 microns thick.

4. The photosensor array of claim 2 wherein the thin overlying silicon filter layer is approximately 0.6 microns thick.

5. The photosensor array of claim 2 further comprising color correction circuitry.

6. The photosensor array of claim 5 wherein the color correction circuitry comprises at least two multipliers and at least one subtractor, configured such that a green output is determined by subtracting a multiple of a signal derived from photosensors of the first type from a multiple of a signal derived from photosensors of the second type.

7. A method of providing a red, a green, and a blue signal representing a color image comprising:
providing a color photosensor array comprising photosensors of a first type having a thick overlying silicon filter layer, photosensors of a second type having a thin overlying silicon filter layer, and photosensors of a third type having no overlying silicon layer; the photosensors of the first type having peak sensitivity in the red, the photosensors of the second type having peak sensitivity in the green;
focusing light from a scene on the photosensor array as an optical image; and
sensing photosensors of the first type to provide the red signal, the second type to provide the green signal, and the third type to provide the blue signal, the red green and blue signals together forming an electronic representation of the optical image.

8. The method of claim 7 wherein the thick overlying silicon layer and the thin overlying silicon layer are single-crystal silicon layers grown atop an implanted pinning region, an absorber layer of each photosensor underlying the pinning region.

9. The method of claim 8 wherein the thick overlying silicon filter layer is approximately 1.2 microns thick.

10. The method of claim 8 wherein the thin overlying silicon filter layer is approximately 0.6 microns thick.

11. The method of claim 8 further comprising passing the red, green, and blue signals through color correction circuitry to improve color resolution of the image.

12. The method of claim 11 wherein the color correction circuitry is configured such that a corrected green output signal is determined by subtracting a multiple of the red signal from a multiple of the green signal.
